(19) United States
(12) Patent Application Publication
(10) Pub. No.: US 2015/0303120 A1
(43) Pub. Date: Oct. 22, 2015

(54) SEMICONDUCTOR PACKAGE STRUCTURE AND METHOD FOR FABRICATING THE SAME

(71) Applicant: UNITED MICROELECTRONICS CORP., Hsin-Chu City (TW)

(72) Inventors: Jubao Zhang, Singapore (SG); Xing Hua Zhang, Singapore (SG); Hong Liao, Singapore (SG)

(73) Assignee: UNITED MICROELECTRONICS CORP., Hsin-Chu City (TW)

(21) Appl. No.: 14/256,989

(22) Filed: Apr. 20, 2014

(51) Int. Cl. H01L 21/66; H01L 23/522; H01L 21/78; H01L 23/00

(52) U.S. Cl. CPC H01L 22/14; H01L 24/98; H01L 24/17; H01L 24/02; H01L 24/94; H01L 23/5226; H01L 21/78; H01L 2224/02372; H01L 2224/1705; H01L 2224/1701; H01L 2224/98; H01L 2224/94

(57) ABSTRACT

A method for fabricating semiconductor package structure is disclosed. The method includes: providing a wafer having a front side and a backside; forming a plurality of through-silicon vias (TSVs) in the wafer and a plurality of metal interconnections on the TSVs, in which the metal interconnections are exposed from the front side of the wafer; performing a monitoring step to screen for TSV failures from the backside of the wafer; and bonding the wafer to a substrate.

### BACKGROUND OF THE INVENTION

1. Field of the Invention

The invention relates to a semiconductor package structure, and more particularly, to a semiconductor package structure allowing monitoring step to be conducted to screen for through-silicon vias (TSVs) failures.

2. Description of the Prior Art

In the electronics industry, there has been an increasing demand for low cost electronic devices with the development of lighter, smaller, faster, more multi-functional, and/or higher performance electronic systems. To meet such demands, multi-chip stacked package techniques and/or systems have been introduced.

In a multi-chip stacked package or system-in-package, multiple semiconductor devices having various functions may be assembled in a single semiconductor package. A multi-chip stacked package or system in package may have a size similar to a single chip package in terms of a planar surface area or footprint. Thus, a multi-chip stacked package or system in package may be used in small and/or mobile devices with high performance requirements, such as, mobile phones, notebook computers, memory cards, and/or portable camcorders. Multi-chip stacked package techniques or system-in-package techniques may be realized using through-silicon-via (TSV) electrodes. However, the use of TSV electrodes may be associated with problems, which may affect performance of the devices in which they are used. Unfortunately, current multi-chip stacked package or system-in-package fabrication process cannot offer a 100% failure screening method for TSVs. Hence, how to resolve this issue has become an important task in this field.

### SUMMARY OF THE INVENTION

It is therefore an objective of the present invention to provide a semiconductor package structure and fabrication method thereof for solving the aforementioned issues.

According to a preferred embodiment of the present invention, a method for fabricating semiconductor package structure is disclosed. The method includes: providing a wafer having a front side and a backside; forming a plurality of through-silicon vias (TSVs) in the wafer and a plurality of metal interconnections on the TSVs, in which the metal interconnections are exposed from the front side of the wafer; performing a monitoring step to screen for TSV failures from the backside of the wafer; and bonding the wafer to a substrate.

According to another aspect of the present invention, a semiconductor package structure is disclosed. The semiconductor package structure includes: a die having a front side and a backside; a plurality of through-silicon vias (TSVs) in the die and a plurality of metal interconnections on the TSVs, in which the metal interconnections are exposed from the front side of the die; and a substrate disposed corresponding to the die.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating semiconductor package structure according to a preferred embodiment of the present invention.

### DETAILED DESCRIPTION

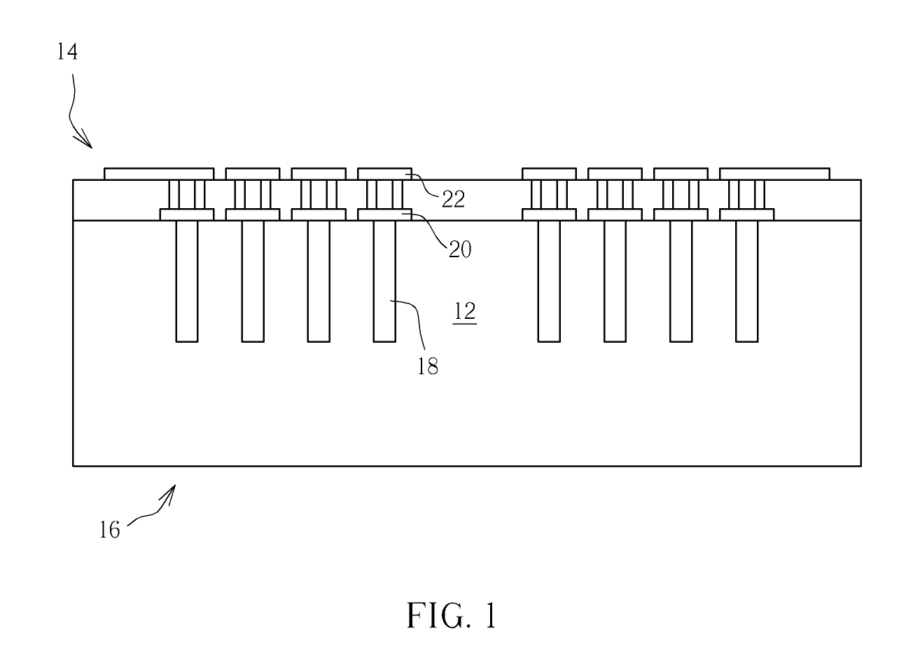

Referring to FIGS. 1-7, FIGS. 1-7 illustrate a method for fabricating semiconductor package structure according to a preferred embodiment of the present invention. As shown in FIG. 1, a silicon wafer 12 having a front side 14 and a backside 16 is provided. A plurality of through-silicon vias (TSVs) 18 are then formed in the wafer 12 and a plurality of metal interconnections 20 are formed on the TSVs 18. Preferably, the metal interconnections 20 are electrically connected to the TSVs 18 directly and are exposed from the front side 14 of the wafer 12. The fabrication of the TSVs 18 may be accomplished by first forming a TSV hole in the wafer 12, and after depositing a plurality of material layers including insulating layer, barrier layer, seed layer, and metal layer into the TSV hole, the material layers are planarized via chemical mechanical polishing (CMP) process to form the TSVs 18 embedded in the wafer 12. As the fabrication of the TSVs 18 is well known to those skilled in the art, the details of which are not explained herein for the sake of brevity.

It should be noted that the wafer 12 could be used to form an interposer with no active devices thereon, and in such instance, the TSVs 18 disclosed in this embodiment would become through-silicon interposers (TSIs) to principally connect a plurality of chips together in a multi-chip stacked package or system-in-package structure. However, for the sake of consistency and simplicity, the term TSV will be used in the following embodiment.

After the metal interconnections 20 are formed, a plurality of redistribution layers (RDLs) 22 are formed on the metal interconnections 20. Preferably, the RDLs 22 are formed on the front side 14 of the wafer 12 and electrically connected to the TSVs 18 via the corresponding metal interconnections 20.

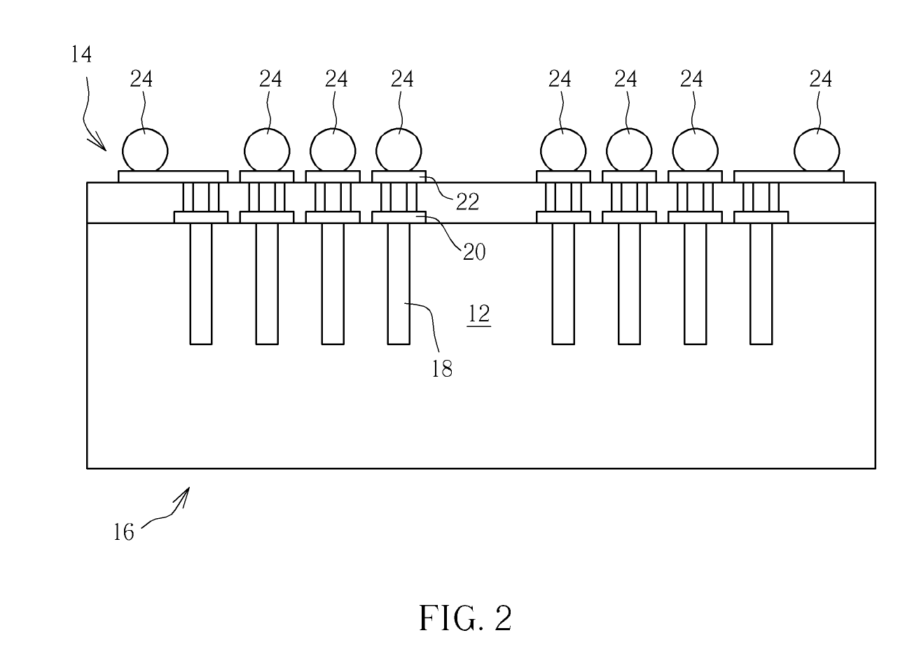

As shown in FIG. 2, a plurality of micro-bumps 24 are then formed on the exposed metal interconnections 20 and RDLs 22 corresponding to each TSVs.

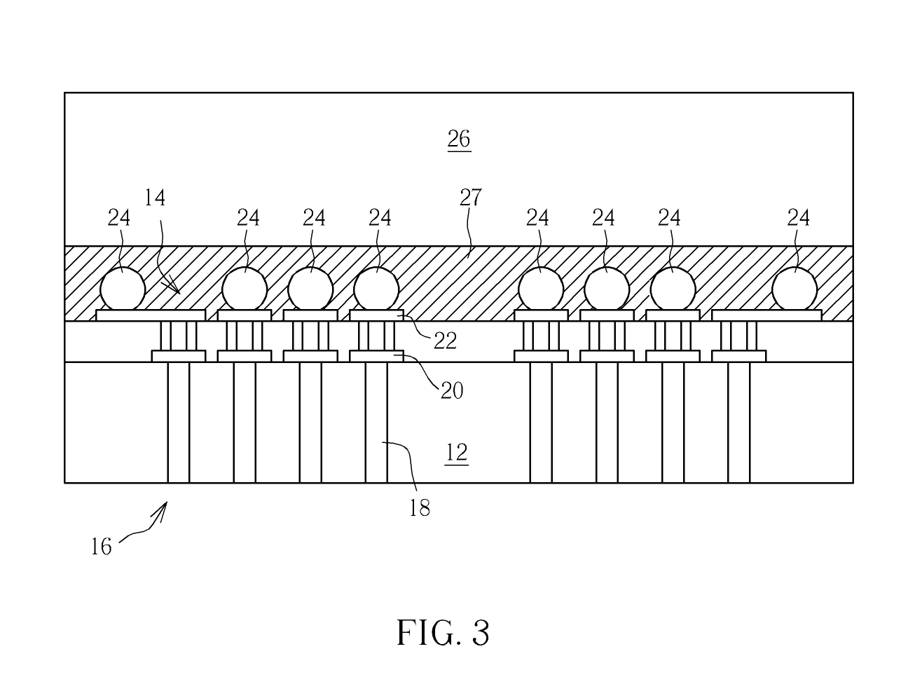

Next, as shown in FIG. 3, the wafer 12 is temporarily bonded to a carrier wafer 26 by an adhesive 27, and a thinning process is conducted to thin the backside 16 of the wafer 12 so that the TSVs 18 embedded in the wafer 12 are exposed.

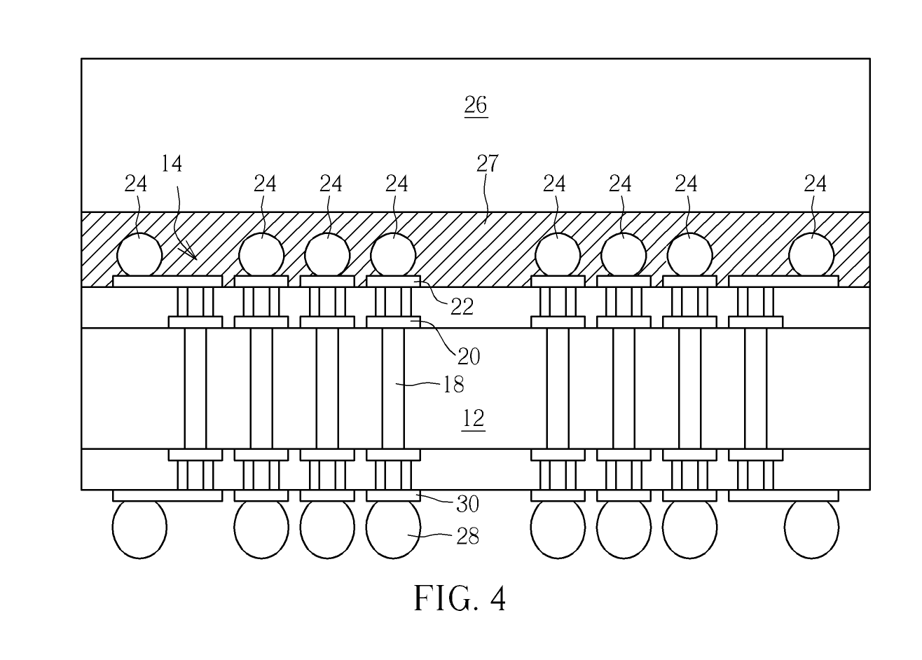

As shown in FIG. 4, a plurality of bumps 28 and additional RDLs 30 are then formed on the backside 16 of the wafer 12, in which the RDLs 30 are electrically connected to the TSVs 18 from the backside 16. A monitoring step is performed thereafter to screen for TSV failures from the backside 16 of the wafer 12 through the bumps 28 and the RDLs 22 and 30.

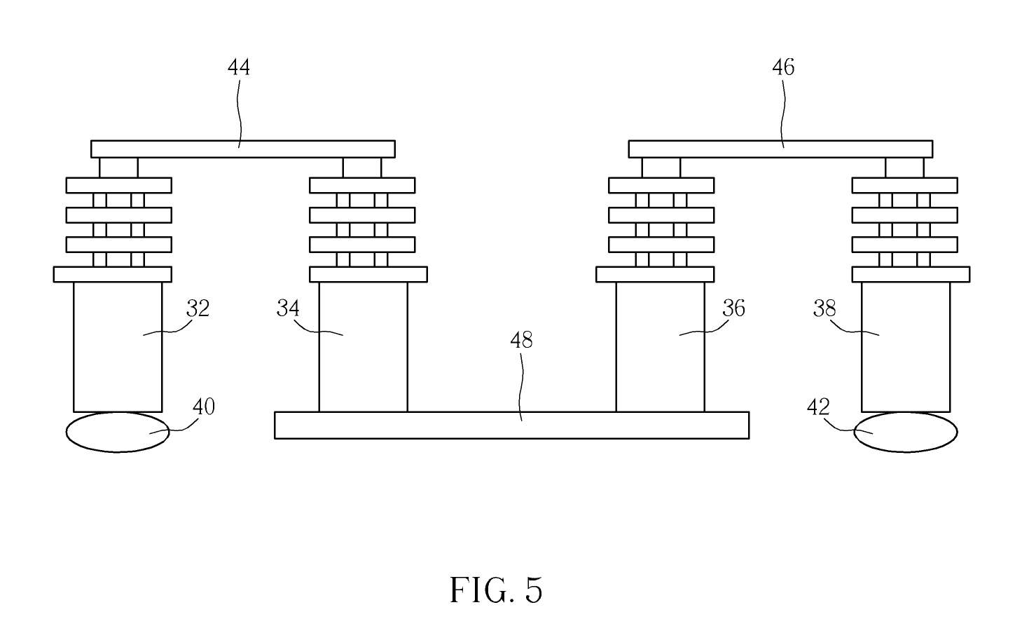

Referring to FIG. 5, which is an enlarged and detail view illustrating a testkey having a plurality of TSVs, metal interconnections, RDLs, and bumps. Preferably, the TSVs, metal interconnections, RDLs, and bumps of the testkey are fabricated along with other TSVs, metal interconnections, RDLs, and bumps of the core circuit region (not shown)_of the same wafer or same batch of wafers.

As shown in FIG. 5, the TSVs 18 embedded in the wafer 12 preferably includes a first TSV 32, a second TSV 34, a third TSV 36, and a fourth TSV 38. The bumps 28 formed on the backside 16 of the wafer 12 preferably includes at least a first bump 40 and a second bump 42, in which the first bump 40 and the second bump 42 are electrically connected to the bottom or backend of the first TSV 32 and the fourth TSV 38 respectively. The RDLs 22 fabricated in FIG. 1 preferably includes a plurality of first RDLs 44 and second RDLs 46 while the RDLs 30 fabricated in FIG. 4 preferably includes a plurality of third RDLs 48. The first RDLs 44 are electrically connecting the first TSV 32 and the second TSV 34 from the front side 14 of the wafer 12 through metal interconnections (not labeled), the second RDLs 46 are electrically connecting the third TSV 36 and the fourth TSV 38 from the front side 14 of the wafer 12 through metal interconnections (not labeled), and the third RDLs 48 are electrically connecting the second TSV 34 and the third TSV 36 from the backside 16 of the wafer 12.

It should be noted that the structure depicted in FIG. 5 intends to demonstrate that an electrically connection is established by using the RDLs to electrically connect all of the TSVs from the first TSV, through the front side RDLs to the backside RDLs and back again to the front side RDLs so that a TSV failure testing could be carried out by simply testing whether an electrical connection is established between the bump connected to the first TSV and the bump connected to the last TSV. For instance, taking the structure revealed in FIG. 5 as an example, a TSV failure testing could be accomplished by determining whether a connection is established from the first bump 40, the first TSV 32, the first RDLs 44, the second TSV 34, the third RDLs 48, the third TSV 36, the second RDLs 46, the fourth TSV 38, and finally to the second bump 42. If a connection is broken at any TSV, a failure for such particular TSV could be identified. Conversely, if the connections of the testkey shown in FIG. 5 were tested to be functional after the failure test, it would represent that the TSVs, metal interconnections, RDLs, and bumps in the core circuit region fabricated along with the testkey were also functional.

It should also be noted that the quantity of the TSVs and the RDLs are not limited to the embodiment disclosed in FIG. 5. That is, the quality of the TSVs could be adjusted according to the demand of the product as long as the TSVs are electrically connected to each other by front side RDLs and backside RDLs in the manner disclosed above so that similar TSV failure testing could be conducted by testing whether an electrical connection is established between the bump connected to the first TSV and the bump connected to the last TSV.

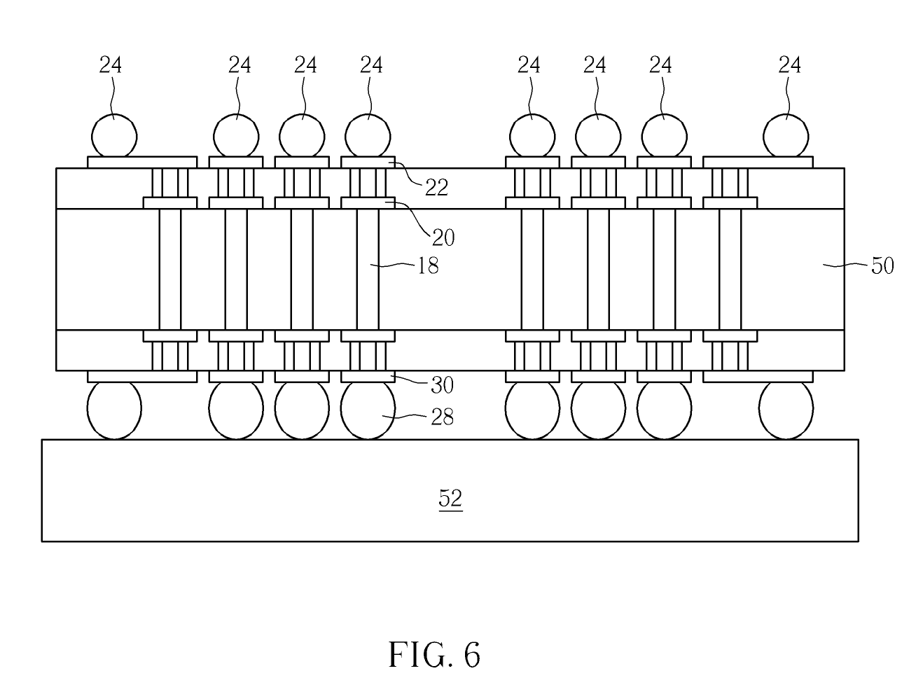

After the failure testing for TSVs is completed, as shown in FIG. 6, a de-bonding process is conducted to remove adhesive and detach the wafer 12 from the carrier wafer 26, and then a dicing process is conducted to dice the wafer 12 into a plurality of dies 50. The dies 50 are then bonded to a substrate 52 via a flip chip bonding process.

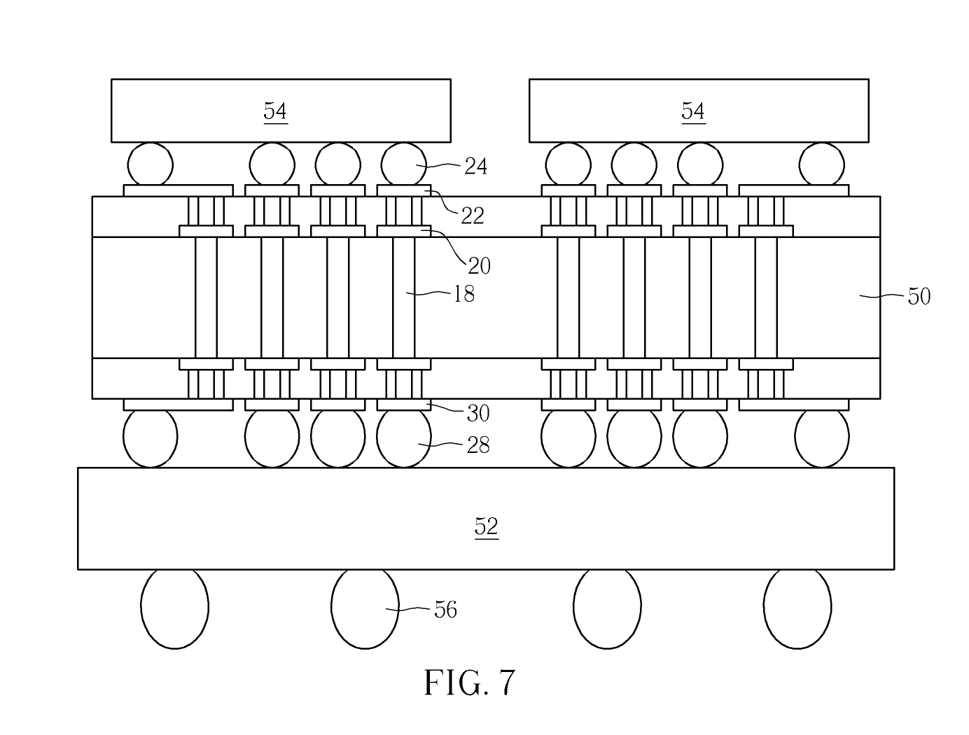

Next, as shown in FIG. 7, additional chips 54 could be formed on the front side of the dies 50 and a plurality of solder balls 56 are mounted on the bottom side of the substrate 52. This completes the fabrication of a semiconductor package structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor package structure, comprising:
providing a wafer having a front side and a backside;
forming a plurality of through-silicon vias (TSVs) in the wafer and a plurality of metal interconnections on the TSVs, wherein the metal interconnections are exposed from the front side of the wafer;
performing a monitoring step to screen for TSV failures from the backside of the wafer; and
bonding the wafer to a substrate.

2. The method of claim 1, further comprising:
forming the TSVs, the metal interconnections, and a plurality of first redistribution layers (RDLs) and second RDLs on the metal interconnections, wherein the first RDLs and second RDLs are electrically connected to the TSVs;
bonding the wafer to a carrier wafer after forming the TSVs, metal interconnections, first RDLs, and second RDLs;
thinning the backside of the wafer so that the TSVs are exposed;
forming a plurality of bumps and third RDLs on the backside of the wafer, wherein the bumps and third RDLs are electrically connected to the TSVs; and
performing the monitoring step through the bumps, the first RDLs, the second RDLs, and the third RDLs.

3. The method of claim 2, wherein the TSVs comprise a first TSV, a second TSV, a third TSV, and a fourth TSV, the plurality of bumps comprise a first bump and a second bump electrically connected to the first TSV and the fourth TSV respectively, the first RDLs are electrically connecting the first TSV and the second TSV from the front side of the wafer, the second RDLs are electrically connecting the third TSV and the fourth TSV from the front side of the wafer, and the third RDLs are electrically connecting the second TSV and the third TSV from the backside of the wafer.

4. The method of claim 3, wherein the monitoring step further comprises:
testing whether a connection is established from the first bump, the first TSV, the first RDLs, the second TSV, the third RDLs, the third TSV, the second RDLs, the fourth TSV, to the second bump.

5. The method of claim 2, further comprising:
de-bonding the wafer from the carrier wafer after forming the bumps and second RDLs;
dicing the wafer to form a plurality of dies;
bonding the dies to the substrate; and
forming a plurality of solder balls on the substrate.

6. The method of claim 5, further comprising forming a plurality of chips on the dies before forming the solder balls.

7. The method of claim 1, wherein the metal interconnections are electrically connected to the TSVs directly.

8. A semiconductor package structure, comprising:
a die, comprising a front side and a backside;
a plurality of through-silicon vias (TSVs) in the die and a plurality of metal interconnections on the TSVs, wherein the metal interconnections are exposed from the front side of the die; and
a substrate disposed corresponding to the die.

9. The semiconductor package structure of claim 8, further comprising:
a plurality of first redistribution layers (RDLs) and second RDLs on the metal interconnections; and
a plurality of bumps and third RDLs on the backside of the die, wherein the first RDLs, the second RDLs, the third RDLs, and the bumps are electrically connected to the TSVs.

10. The semiconductor package structure of claim 9, wherein the TSVs comprise a first TSV, a second TSV, a third TSV, and a fourth TSV, the plurality of bumps comprise a first bump and a second bump electrically connected to the first TSV and the fourth TSV respectively, the first RDLs are electrically connecting the first TSV and the second TSV from the front side of the die, the second RDLs are electrically connecting the third TSV and the fourth TSV from the front side of the die, and the third RDLs are electrically connecting the second TSV and the third TSV from the backside of the die.

11. The semiconductor package structure of claim 10, further comprising a plurality of chips on the dies.

12. The semiconductor package structure of claim 8, further comprising a plurality of solder balls on the substrate.
